(19) United States
(12) Patent Application Publication
(10) Pub. No.: US 2026/0328410 A1
(43) Pub. Date: Oct. 22, 2026

(54) AIR HEAT EXCHANGER WITH PELTIER ELEMENTS AND A METHOD FOR INSTALLING AN AIR HEAT EXCHANGER WITH PELTIER ELEMENTS

(71) Applicant: Rikard BERGSTEN, Göteborg (SE)

(72) Inventors: Rikard BERGSTEN, Göteborg (SE); Sven HELLESTAM, Göteborg (SE)

(73) Assignee: Rikard BERGSTEN, Göteborg (SE)

(21) Appl. No.: 19/109,466

(22) PCT Filed: Sep. 6, 2023
(86) PCT No.: PCT/EP2023/074480

§ 371 Date: Mar. 6, 2025

(30) Foreign Application Priority Data
Sep. 7, 2022 (SE) 2251037-4

(51) Int. Cl. F24F 1/0097; F24F 7/007; F24F 11/46; F24F 12/00

(52) U.S. Cl. CPC F24F 1/0097; F24F 7/007; F24F 11/46; F24F 12/006; F24F 2221/17

(57) ABSTRACT

This invention relates to an air heat exchanger device for heating and/or cooling and/or dehumidifying of supply and exhaust air of a room, comprising
a heat exchanger unit arranged to connect an inside of a room with an outside environment, said heat exchanger unit including a longitudinal dividing wall member, which divides said heat exchanger unit into two separate, longitudinal, first and second, flow channels,
at least two fans arranged for conveying supply air from the outside environment to the inside of the room and for conveying exhaust air from the inside of the room to the outside environment, via said flow channels,
at least one heat exchanger part arranged in each flow channel,
at least two temperature control members connected to one another via at least one Peltier element, wherein a first temperature control member is connected to a first heat exchanger part in said first flow channel and a second temperature control member is connected to a second heat exchanger part in said second flow channel, wherein said two temperature control members, are plate shaped and at least partly, form a part of said longitudinal dividing wall member.

### TECHNICAL FIELD

The invention relates to an air heat exchanger device for heating and/or cooling and/or dehumidifying of supply and exhaust air of a room, comprising a heat exchanger unit arranged to connect an inside of a room with an outside environment. The heat exchanger unit includes a longitudinal dividing wall member, which divides the heat exchanger unit into two separate longitudinal, first and second, flow channels. At least two fans are arranged for conveying supply air from the outside environment to the inside of the room and for conveying exhaust air from the inside of the room to the outside environment (6), via said flow channels. At least one heat exchanger part is arranged in each flow channel (2A, 2B) and at least two temperature control members are connected to one another via at least one Peltier element, wherein a first temperature control member is connected to a first heat exchanger part in said first flow channel and a second temperature control member is connected to a second heat exchanger part in said second flow channel.

### BACKGROUND

There has for long been a general strive to improve energy efficiency regarding heating and cooling of buildings. In the prior art there exist a plurality of suggested designs including peltier elements to obtain improved efficiency.

KR 10 2005 00 38 256 A describes a device for heating and cooling air and combined dehumidification. The device includes two Peltier elements with heat sinks connected to them, with a fan located between the heat sinks. On the other side, the Peltier elements are each provided with heat dissipation plates. Heat sinks, Peltier elements and heat transfer plates are all arranged in a row along an axis, which axis corresponds to the axis of rotation of the fan.

JP 02-251 021 A describes the use of a Peltier element in underfloor heating, with two different heat storage media being used using off-peak electricity.

DE 10 2005 013 926 A1 describes the use of a Peltier element, to which a heat exchanger is coupled, for cooling, heating or temperature control of a so-called application tool, in particular in the wellness or medical field.

DE 196 00 470 C2 describes an H-shaped thermo-compact device for heating, cooling and dehumidifying media and for heat recovery. The device has two separate channel systems through which the flow always goes in the same direction. A plurality of thermos blocks that can be heated and cooled using Peltier elements are connected in parallel in this device, and the device makes use of the different temperatures in the two channel systems. Condensed water, which occurs during dehumidification, is drained off by intentionally tilting the device. DE 10 2007 013 779 A1 also describes a device for cooling or heating air, which also has a heat accumulator which also assumes the function of a cooling element, which in turn is also coupled to a Peltier element. During operation, heat is either extracted from or supplied to the heat accumulator, with no exchange with outside air taking place when the room air is cooled. When using several heat accumulators connected with Peltier elements, these are connected in parallel to increase the capacity of the system.

From EP 266 05 25 there is known a decentralized ventilation device for heating, cooling and dehumidifying incoming and outgoing air of a room, comprising an air duct for connecting an inside of the room to an outside environment, wherein the air duct includes a longitudinal division, dividing it into a first and a second flow duct. An axial fan is arranged in each flow duct, enabling two operating states, supply of air from the outside environment to the inside of the room, and vice-versa. At least one heat accumulator is arranged in the air duct between the axial fans and the outside environment. On the other side of the fans temperature control elements are arranged, connected to one another via a Peltier element, wherein the Peltier element is located between them.

Known heating and cooling devices including peltier elements do present disadvantages, e.g. insufficient efficiency and/or too space consuming and/or too costly.

### SUMMARY OF THE INVENTION

It is an object of the invention to provide an improved heating and cooling device including peltier elements, which is achieved by a concept as defined in the appended claims.

This novel air heat exchanger has been shown in tests to be able to give extremely good yields, with a COP number of above 6, i.e. about 6 times higher heat output power than input power, thanks to a design using optimal heat transfer to air by means of Peltier elements in a completely new way. In some test COP above 8 and even above 10 have been achieved, even really surprising high results of COP 12 have been achieved.

According to further aspect of the invention:
there is a plurality of peltier elements (21) arranged in between said two plate shaped temperature control members (24A, 24B), wherein preferably there are arranged a plurality of rows (21A, 21B) of peltier elements (21) and a plurality of peltier elements (21) in each row (21A, 21B), which may provide improved efficiency,
the fans (10, 11) are arranged outside of said heat exchanger unit (2), which may provide improved efficiency, wherein preferably fans (10, 11) are attached adjacent an outer end of said heat exchanger unit (2) and more preferred being pivotally arranged, most preferred by an unfold and/or fold arrangement arranged to pivot said fans (10,11).
The heat exchanger parts (23A, 23B) comprise a plurality of longitudinally and transversally extending exchanger plates (20) forming longitudinally and transversally extending gaps, wherein preferably said gaps are larger near said plate shaped temperature control members (24A, 24B) than at the periphery, which may provide improved efficiency,
the heat exchanger unit (2) has a circular cross-sectional shape, wherein preferably the diameter (D) is less than 200 mm, and more preferred that each flow channel has a semi-circular cross-section, which may provide improved efficiency and/or more easy mounting and/or dismounting.
the peltier elements (21) are electrically supplied via the temperature control members (24A, 24B) one acting plus pole and the other acting minus pole, wherein preferably the polarity of said electrical supply may be changed, which may provide for improved efficiency and/or compactness.
each peltier element (21) is arranged with a pair of contact pins (210, 211) protruding in opposite directions, one contact pin (210, 211) being in contact with a first contact member (25A) in contact with the one pole and one contact pin (210, 211) being in contact with a second contact member (25B) in contact with the other pole, wherein preferably each of said contact members (25A, 25B) comprises at least one layer (251) of electrically conducting material and at least one layer (250) of an electrically isolating material, wherein more preferred at least one of said layers (250, 251) is compressible.
each of said fans (10, 11) is arranged to supply air in one direction only, wherein change between cooling and heating respectively is achieved by change of polarity of temperature control members (24A, 24B),
said second and first flow channels (2A, 2B) have different cross-sectional areas, wherein preferably the size of each flow channel is achieved by means of a non-central position of said longitudinal dividing wall member (22).
the thickness (t) of the exchanger plates (20) is within the range of D/1000<t<D/100, wherein D corresponds to the largest cross-sectional width of the flow channels (2A, 2B) surrounding the exchanger plates (20), wherein preferably the gap between neighboring exchanger plates (20) is within the same range, i.e. D/1000<t<D/100 and more preferred that said gap is larger than said thickness (t), whereby increased efficiency may be achieved.
control unit (8) controls the speed of the fans (10,11) and the voltage over the peltier elements (21) according to the input of sensors connected to the control unit (8) to incrementally get closer to the optimal working point for the operating Peltier elements (21).

Further beneficial aspects related to a method of installing and/or maintaining are apparent in regard to claims 15 to 17 and also details mentioned in the detailed description.

### BRIEF DESCRIPTION OF FIGURES

In the following the invention will be described in more detail with reference to the appended figures, in which:

FIG. 1 shows a schematic perspective view of a heating and cooling device according to the invention,

FIG. 2 schematically shows a cross-sectional view along line II-II in FIG. 1, and

FIG. 3 schematically shows a cross-sectional view along line III-III in FIG. 2.

### DETAILED DESCRIPTION

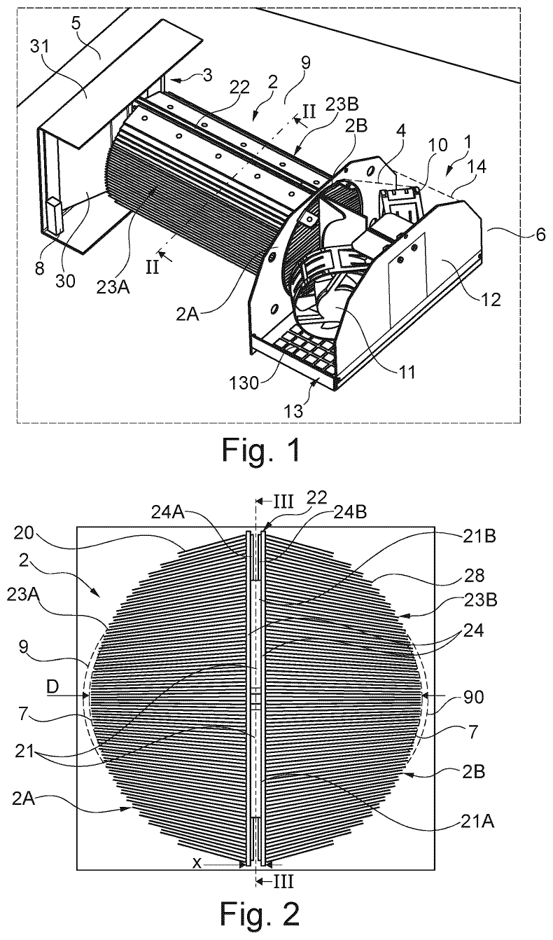

With reference to FIG. 1, there is schematically shown an air heating and cooling device according to the invention installed in a house wall 9 between a room 5 and the outdoor environment 6. The heating and cooling device comprises an outer fan housing 1 attached to outside of the wall 9, a (preferably cylindrical) heat exchanger unit 2 arranged (at least partly) within a duct 90 through the wall 9 and an inner air distributor 3. (ref. 4 refers to a flexible casing, e.g. fabric, and is described in more detail below).

Preferably the exchanger part 2 is cylindrical intended to be mounted in a passage 90, preferably a cylindrical hole, through the housing wall 9. Thanks to the high efficiency of the heating and cooling device diameter D may be relatively small fulfilling its purpose in many installations, e.g. having diameter below 200 mm, preferably a diameter of 150 mm or less. Hence, it may take up very little space compared to prior art air heating and cooling devices. The relatively small diameter also allows for an easier drilling operation, in many materials by handheld drills.

In the outer fan housing 1 there are arranged two fans 10, 11, that in their active position is arranged at the outside of the wall 9 of the building. The housing comprises two side walls (preferably vertical), an upper U-formed roof part 14 (merely indicated in FIG. 1, to show details within), preferably arranged along the outer edges of the side walls 12, and a bottom part 13. One of the fans 10 supplies air from outside 6 into a first flow channel 2A and the other fan 11 passes exhaust air out from the room 5 via a second flow channel 2B. Hence, each fan is connected to its own flow channel 2A resp. 2B through the heat exchanger part 2. The fan housing 1 is preferably arranged with air intake and outflow, respectively, via a downwardly directed bottom part 13, preferably including a perforated downwardly directed bottom portion 130. There is arranged a tubular part 4 (merely indicated in FIG. 1) between each fan 10, 11 and each channel 2A, 2B, respectively, ensuring that the flows are separated. Preferably, the tubular parts 4 are flexible (e.g. fabric), which may be beneficial regarding mounting and maintenance of the device, as explained more in detail below.

Within the heat exchanger unit 2 the flow channels 2A, 2B are separated by means of a diametrically arranged, longitudinal wall unit 22, that preferably is arranged vertically. At the periphery of the heat exchanger unit 2 there may be arranged a cover/housing 7 that seals each flow channel through the heat exchanger unit 2, (as indicated in FIG. 2), preferably the same flexible material as used for the tubular parts 4 for the fans 10, 11.

In a preferred embodiment the fans 10, 11 are collapsibly arranged. Preferably pivotably or slidably arranged so that they can be swung in and swung out, wherein when in the swung in position the fans 10, 11 are accommodated within the diameter D of the heat exchanger unit 2. Thanks to this design detail and use of flexible tubes 4, the heat exchanger unit 2 with fans 10, 11 can be inserted in and taken out through the same hole 90. It is foreseen that this feature may be the subject for protection per se, e.g. by means of a divisional application, since the benefit thereof may be beneficial in various kinds of heat exchangers.

In a preferred embodiment also the fan housing 1 is collapsible, e.g. by means of hinges (not shown) in the roof part 14, and at least partly indirectly supported by the walls of the hole 90, such that also the fan housing 1 may be mounted from the inside, without the need to operate at the outside, e.g. without any need to assemble, e.g. screwing or unscrewing, anything located on the outside of the wall 9 from the outside. As is evident this feature is especially beneficial in relation to multi storage buildings, e.g. in connection with mounting and or maintenance. It is foreseen that this feature may be the subject for protection per se, e.g. by means of a divisional application, since the benefit thereof may be beneficial in various kinds of heat exchangers.

There are foreseen various solutions to enable folding (to be able to mount and take the unit out, respectively) and unfolding (to its running position) by use of fold and unfold arrangements, respectively. Hence, an unfold arrangement may be used to swing the fans and or fan housing pivotally when the unit is pushed out to its end position, e.g. including a knob, wire or magnet, to activate unfolding. Similarly, a fold arrangement may be used to swing the fans and or fan housing further when the unit is taken out of the hole 90, e.g. including a magnet, a wire or wellcro.

FIG. 2 shows a cross-sectional view of a cylindrical heat exchanger unit 2. It is shown that the dividing wall 22 comprises temperature control elements 24A, 24B, which are in the form of two electrically conducting plates 24A, 24B, forming outer layers of the dividing wall 22. The two plates 24A, 24B are positioned at a distance sufficient to accommodate the peltier elements between them, e.g. 2-8 mm, from each other. The plates preferably have high thermal conductivity, preferably above 200 W/mK, e.g. copper. In the gap between two plates 24A. 24B there are arranged a plurality of Peltier elements 21, with their flat sides facing the inner side of each one of the two plates 24A, 24B. Preferably the peltier elements, and/or the temperature control members side facing the peltier elements, are covered with thermal paste or thermal adhesive, such that the temperature gradient is kept low.

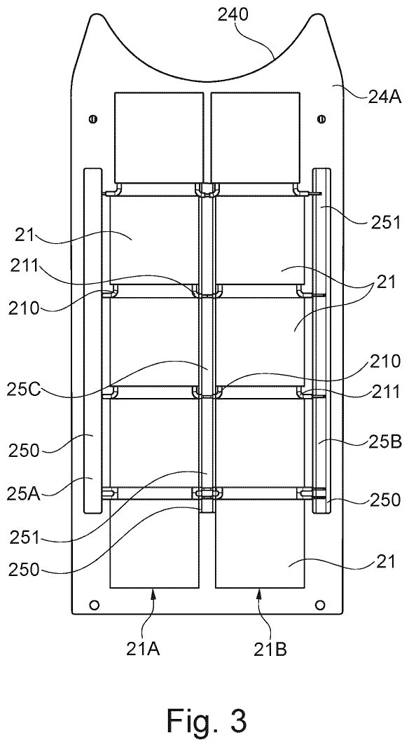

In the embodiment shown, there are a plurality of rows 21A, 21B, wherein each row includes a plurality of Peltier elements 21, preferably at least two Peltier elements 21 in an upper row 21B and at least two in a lower row 21A, more preferred between three to ten Peltier elements 21 in an upper row 21B and between three to ten in a lower row 21A. The plurality of Peltier elements 21 in each row 21A, 21B, both serially and parallelly, are connected with each other by means of contact members 25A, 25B, 25C as shown in FIG. 3.

Peltier elements have individual differences due to the manufacturing process and it is thus generally recommended that each element is voltage controlled individually. A reasonably often used method in prior art is parallel distribution of power with the same voltage over several peltier elements. Most peltier elements on the market have a nominal voltage range for small temperature gradients of e.g. 3-18 Volts, with the optimum working point with regard to efficiency often in the range 4-7 volts (depending on the temperature and temperature gradient over the element). In our preferred embodiment there are arranged two rows of parallel distributed elements but with the rows arranged in series, thus creating a serial connection of parallelly distributed elements. Test have shown that this has proven to be enough to allow for individual differences from the manufacturing process while allowing the use of a preferred voltage supply of 12V. It is beneficial both in terms of current losses, which decrease as a higher voltage gives a lower current for the same amount of electrical power, and in terms of ability to directly power the system via solar panels, that are typically manufactured for a nominal voltage of 12 Volts.

As shown in FIG. 3 each Peltier elements 21 is arranged with a pair of contact pins 210, 211. Further it is shown that each contact members 25A, 25B, 25C comprises one side with a longish isolating layer 250 and the other side with a longish contact foil 251. The two outer contact members 25A, 25B are oppositely arranged, one 25A having the contact foil 251 in contact with/facing a first plate 24A and the other 25B having the contact foil 251 in contact with/facing a second plate 24B. The central contact member 24C is arranged with isolating layers 250 in contact with/facing both plates 24A, 25B, i.e. not in direct electrical contact with any of the plates 24A, 24B, but having a contact foil 251 arranged as an intermediate layer facilitating electrical contact between the two rows 21A, 21B. The Peltier elements 21 are electrically supplied via the temperature control members 24A, 24B, one acting plus pole and the acting minus pole, which polarity may be controllable switched.

Hence, with the preferred electrical distribution system one electrical pole is distributed in a first temperature control member/plate 24A, which connects to the first row of peltier elements by an electrically isolating compressible material covered on one side with an electrically conducting material 25A towards the temperature control member 24A and the peltier elements 21A, connecting them. The two rows are then connected with each other with two stripes of electrically isolating compressible material 25C covered on one side with an electrically conducting material-away from both temperature control members 24A and 24B so that they connect the two rows to each other only. Lastly, the last row of peltier elements 21B is connected similarly via 25B to the other temperature control member 24B which is connected to the other electrical pole.

Each peltier element 21 has a first contact pin 210 connected to the plus pole and a second contact pin 211 connected to the minus pole. In the lower row 21A all Peltier elements have one contact pin 210 connected to the contact foil 251 of a lower contact member 25A and the other contact pin 211 connected to the central contact foil 251 of the central contact member 25C. In the upper row 21B all Peltier elements have one contact pin 211 connected to the contact foil 251 of the upper contact foil 25B and the other contact pin 210 connected to the central contact foil 251 central contact member 25C. Preferably the electrically isolating layer 250 is a compressible material, which may assure that the electrically conducting foils 251 are securely pressed in contact with the respective plus pole/plate 24A, 24B, i.e. such that all peltier elements 21 will have one contact pin 210 in contact with one temperature control member 24A and the other contact pin 211 in contact with the other temperature control member 24B.

The Peltier elements 21 have a hot and a cold side. By reversing the pole, one can thus change, so that either the hot or cold side is in contact with the supply air duct 2A. Thus, the heat exchangers 23A, 23B can be used both to heat and to cool a room 5.

Further, within the heat exchanger unit 2, in contact with the outer side of each plate 24A, 24B there are arranged (preferably fixedly attached) a plurality of longitudinally and transversally extending exchanger plates 20, forming two heat exchanger parts 23A, 23B.

Hence, there is arranged one heat exchanger part 23A, 23B in each flow channel 2A, 2B, which exchange heat with the air in each flow channel 2A, 2B, respectively, and also with the plate 24A, 24B to which it is connected.

The exchanger plates 20 are in the form of thin blades, having a thickness t that may depend on the transversal length of the plates, which define thin gaps between them. In the Fig it is shown an embodiment where the exchanger plates have a free outer end. In a preferred embodiment the exchanger plates 20 may be formed by folding one or more metal sheet/s, such that each outer end is connected to a neighboring exchanger plate 20 by means of a bridge part (not shown). The thickness of the plates 20 may be substantially proportional to the radius D/2 of the duct 90, e.g. D/1000<t<D/100. Preferably, the gap distance is within the same range, i.e. D/1000<t<D/100 and preferably the gap is larger than the thickness t. It is evident that the basic principle described for a circular unit is applicable also for units having rectangular, hexagonal, etc. shape, which may easily be installed in connection with construction of new buildings, wherein the smallest centrally measured cross-sectional width may be seen to correspond to D. For applications having a diameter D less than 250 mm the thickness may be about 0,1-0.8 mm (preferably 0.2-0,4 mm). For large applications having a diameter D that is above 300 mm, the thickness may be more than 1 mm. Preferably, the blades are made in a material having high thermal conductivity, preferably above 200 W/mK, e.g. aluminum.

The exchanger plates 20 are preferably arranged in such a way that the gap is larger closer to the temperature control member 24 than at the periphery. The gap is preferably between 1.5 to 2 times larger next to the temperature control member 24 than at the periphery, e.g. approx. 1-1,5 mm next to the plates 24A, 24B and approx. 0.5-0,8 mm at the periphery. In a preferred embodiment the flow channel may have a semi-circular shape (as shown in FIG. 2), wherein the chorda, e.g. diameter, forms the basis for the inner ends of the exchanger plates 20.

Thanks to this configuration, extra high efficiency may be obtained, partly due to improving for the possibility of providing laminar flow, and partly due to improving the flow pattern by providing a higher flow around the heat exchanger portions closer to temperature control elements 24, i.e. having the highest flow adjacent the hottest and coldest parts, respectively, and the lowest flow at the periphery i.e. farthest away from the temperature control members 24. In other words the flow, seen transversally, may be substantially proportional to the temperature gradient of the heat exchanger, such that a molecule of air traveling at the periphery have an equal chance of heating or cooling as a molecule traveling near the temperature control member 24. Since heat or cold is flowing from the temperature control member 24 through the exchanger plate 20 to the periphery it follows that the temperature gradient to the air in the exchanger plate 20 decreases towards the periphery. In a laminar flow heat is transferred through conduction in the air, as each molecule is traveling a straight line, and thus the chance of heating a single molecule depends on the time in the channel and the distance from the exchanger plate 20. It is foreseen that this feature may be the subject for protection per se, e.g. by means of a divisional application, since the benefit thereof may be beneficial in various kinds of heat exchanger. The flow may preferably be in the range of 0,5 5 m/s, more preferred 1-3 m/s.

It should be noted, if significant differences in air flow between exhaust and fresh air is required, that the chorda may be set offset to the diameter so that the exhaust flow channel may differ in aggregate volume compared to the fresh air flow channel, to compensate for the differences in flow volume between them.

It should also be noted that the entrance region with turbulent flow is relatively short in comparison to the length of the channel between the exchanger plates 20, which means that laminar flow mostly may determine the heat exchange. For a given pressure gradient along the channel between the exchanger plates 20, created by the fans 10, 11, the average speed of the flow will increase from the periphery where the channel between the exchanger plates 20 is narrower towards the temperature control member 24 where the channel is wider, thus making the air stay longer in the channel where the temperature gradient is lesser. The temperature gradient of the air decreases as the air travels through the channel between the exchanger plates 20 on its way in (fresh air) or out (exhaust air). Peltier elements are more efficient when the temperature gradient across them are small or even negative, so that arranging the beginning of the fresh air channel opposite the end of the exhaust air channel and vice versa, provides a more optimal working point for the peltier elements than would e.g. a parallel flow solution.

The inner air distributor 3 has distribution walls 30, which ensure that supply air flows out in one direction and exhaust air is taken in on the other side. On this device 3 there is suitably also arranged a control unit 8, including processor, circuit board, etc. The air heat exchanger device may be operated manually via the control unit 8, but it is preferably operated partially or fully automatically either individually and/or by having a central control unit (not shown, e.g. an app in a smart phone), e.g. using wire less communication with the control unit 8.

The control unit 8 (and/or central control unit) may be connected to several sensors, e.g. including an outdoor sensor (not shown) for measuring humidity and/or temperature in the external environment 6 and/or an indoor sensor (not shown), for measuring humidity and/or temperature on the inside of the room 5, and/or at least one flow channel sensor (not shown) for measuring flow and/or humidity and/or temperature in at least one of the flow channels 2A, 2B, preferably at least one sensor in each.

The control means may use the temperature differences between the inside and outside to determine whether the air heat exchanger device is to be operated for heating, cooling, dehumidification or for heat recovery.

The control unit 8 (and/or central control unit) may be used to determine the direction of rotation and/or the duration of rotation and/or the rotational speed of at least one, or both, of the fans 6 and/or the operating level of the Peltier elements 21 to adjust the heating/cooling capacity of the first and the second heat exchanger parts 23A, 23B, depending on the input from sensors. Typically, the design according to the invention will increase heat exchange capacity drastically compared to traditional air heat exchangers. Generally, the invention will provide a COP number of above 6, i.e. more than six times higher heat output power than input power.

For the specific peltier elements used, an optimal working point can be measured, where the efficiency will be at its highest. Such measurements, taken before production, can and should preferably be used by the control unit 8 to incrementally adjust parameters, e.g. fan speeds and voltage over the peltier elements, to run the heat exchange process close to or even at the optimal working point.

For each absolute temperature of the peltier element(s) and for each temperature difference over the peltier elements the efficiency of the heat pump can be determined from measurements or calculations and it will show a peak at some voltage relative to the temperature difference at a specific temperature. The temperature difference is in turn dependent on both the supplied voltage and the speed of the fans.

In the preferred embodiment the control unit 8 makes use of an algorithm that automatically may adjust one or more parameters to control the heat exchanger to operate at or near the optimal/peak conditions of the peltier elements 21. The algorithm may automatically control whether it is more important to maintain the voltage (e.g. because of limits in the current supply) or the speed of the fans (e.g. due to ventilation/air rate exchange demands or because of limits to noise levels) and, if voltage is to be maintained automatically adjust (e.g. incrementally) the fan speed, e.g. increase the fan speed if the temperature difference is too low for optimal efficiency or vice versa, and if fan speed is to be maintained, adjust (e.g. incrementally) the voltage, e.g. if voltage is too low for optimal efficiency increase the voltage or if voltage is too high for optimal efficiency decrease the voltage. For obvious reason one may, if neither voltage nor fan speed need to be maintained, incrementally change both in the desired direction until the heat pump operates at near optimal efficiency.

In a first operating mode “dehumidifying” supply air may be conveyed in one of the two flow channels 2A, 2B, with the heat exchanger part 23A, 23B located in this flow channel cooling the supply air to a temperature equal to or lower than the dew point temperature. In the other flow channel, exhaust air is then conveyed to the outside and is used to cool the other heat exchanger part.

In a second “cooling” operating mode, air is likewise conveyed as mentioned above, but only cooled to a temperature above the dew point temperature, e.g. to temperatures such that its humidity is in a climatically comfortable range, for example between 40% and 90%, preferably 80%.

In a third operating mode “heat recovery”, which can be set when the outside temperature is lower than the inside temperature, the exhaust flow channel works as heat accumulator for heat recovery.

In a fourth mode of operation “heating”, one of the two flow channels 2A, 2B with supply air the heat exchanger part in that channel heats the supply air to a predetermined temperature. With the ventilation device described above, it is possible to implement a decentralized ventilation device that has the functions of heat recovery and dehumidification and can also be operated in warmer regions. At the same time, the ventilation device is also suitable for use in areas with severe frost, i.e. in colder regions.

It is evident for the skilled person that the above description is not limiting the scope of protection, but that there exist a variety of alternatives that may be applied providing the same basic function of the invention. For instance, it is possible to arrange the fans on the inside of the wall and still achieve good results, but possibly that may increase the noise on the inside of said wall. Further, as is evident a watertight sealant is preferably used to seal around the hole in the wall and that means may be provided to compress such a watertight sealant when movement of the unit is to be performed, e.g. when pulling the duct with the outer hood attached to it, towards the inside. Further, it is evident that it is possible and sometimes beneficial to take the exhaust air from a remote location, e.g. a bathroom, via a ducting system. The same may apply to the fresh air supply.

1. Air heat exchanger device for heating and/or cooling and/or dehumidifying of supply and exhaust air of a room, comprising,
a control unit arranged to operate said air heat exchanger device,
a heat exchanger unit arranged to connect an inside of a room with an outside environment, said heat exchanger unit including a longitudinal dividing wall member, which divides said heat exchanger unit into two separate, longitudinal, first and second, flow channels,
at least two fans, one fan arranged for conveying supply air from the outside environment to the inside of the room and one fan for conveying exhaust air from the inside of the room to the outside environment, via said flow channels,
at least one heat exchanger part, arranged in each flow channel,
at least two temperature control members connected to one another via at least one Peltier element, wherein a first temperature control member is connected to a first heat exchanger part in said first flow channel and a second temperature control member is connected to a second heat exchanger part in said second flow channel, wherein said two temperature control members, at least partly, form a part of said longitudinal dividing wall member
wherein said at least two fans directly convey supply air and exhaust air, respectively, into said flow channels and that said two temperature control members, are in the form of two electrically conducting plates having a thermal conductivity above 200 W/mK forming outer layers of said dividing wall, and wherein each of said heat exchanger part, comprise a plurality of longitudinally and transversally extending exchanger plates in contact with the outer side of said electrically conducting plate.

2. Air heat exchanger device according to claim 1, wherein there is a plurality of peltier elements arranged in between said two plate shaped temperature control members, wherein preferably there are arranged a plurality of rows of peltier elements and a plurality of peltier elements in each row.

3. Air heat exchanger device according to claim 1, wherein in that said fans are arranged outside of said heat exchanger unit.

4. Air heat exchanger device according to claim 3, wherein in that said fans are attached adjacent an outer end of said heat exchanger unit and preferably being pivotally arranged.

5. Air heat exchanger device according to claim 4, wherein an unfold and/or fold arrangement arranged to pivot said fans.

6. Air heat exchanger device according to any preceding claim 1, wherein in that said heat exchanger parts comprise a plurality of longitudinally and transversally extending exchanger plates forming longitudinally and transversally extending gaps, wherein preferably said gaps are larger near said plate shaped temperature control members than at the periphery.

7. Air heat exchanger device according to any preceding claim 1, wherein that said heat exchanger unit has a circular cross-sectional shape, wherein preferably the diameter (D) is less than 200 mm, and more preferred that each flow channel has a semicircular cross-section.

8. Air heat exchanger device according to claim 2, wherein the peltier elements are electrically supplied via the temperature control members, one acting plus pole and the other acting minus pole, wherein preferably the polarity of said electrical supply may be changed,

9. Air heat exchanger device according to claim 8, wherein in that each peltier element is arranged with a pair of contact pins protruding in opposite directions, one contact pin being in contact with a first contact member in contact with the one pole and one contact pin being in contact with a second contact member in contact with the other pole, wherein preferably each of said contact members, comprises at least one layer of electrically conducting material and at least one layer of an electrically isolating material, wherein more preferred at least one of said layers is compressible.

10. Air heat exchanger device according to claim 1, wherein each of said fans is arranged to supply air in one direction only, wherein change between cooling and heating respectively is achieved by change of polarity of temperature control members.

11. Air heat exchanger device according to any preceding claim 1, wherein said second and first flow channels have different cross-sectional areas, wherein preferably the size of each flow channel is achieved by means of a non-central position of said longitudinal dividing wall member.

12. Air heat exchanger device according to claim 1, wherein the thickness (t) of the exchanger plates is within the range of D/1000<t<D/100, wherein D corresponds to the largest cross-sectional width of the flow channels, surrounding the exchanger plates.

13. Air heat exchanger device according claim 12, wherein the gap between neighboring exchanger plates is within the same range, i.e. D/1000<t<D/100 and preferably that said gap is larger than said thickness (t).

14. Method of operating an air heat exchanger device according to claim 1,
measuring an optimal working point of the specific peltier elements used in the air heat exchanger device, including that said control unit controls the speed of the fans and/or the voltage over the peltier elements according to the input of sensors connected to the control unit to, preferably incrementally, adjust the parameter fan speed and/or voltage over the peltier elements to get closer to said optimal working point for the operating Peltier elements.

15. Method of installing and/or maintenance of an air heat exchanger device according to claim 1,
including the steps of,
using a hole through a wall,
inserting and/or taking out at least the heat exchanger unit with fans through said hole from inside of said wall, wherein said fans are pivotally arranged and by pivoting said fans to fit within the space of the hole and thereafter push said heat exchanger unit with fans from the inside through said hole for mounting and pull for dismounting, respectively, wherein preferably said hole is made by drilling and said heat exchanger unit is circular, wherein more preferred also a fan housing is collapsible and fits within the space of the hole enabling pushing of said fan housing from the inside through said hole for mounting.
